(19) United States
(12) Patent Application Publication
(10) Pub. No.: US 2003/0155656 A1
(43) Pub. Date: Aug. 21, 2003

(54) Anisotropically conductive film

(76) Inventors: Cindy Chia-Wen Chiu, San Dimas, CA (US); David Hsein-Pin Chen, Buena Park, CA (US); Philip Yi Zhi Chu, Monrovia, CA (US); Hsiao Ken Chuang, Arcadia, CA (US); H. Paul Barker, Sherman Oaks, CA (US)

Correspondence Address: Heidi A. Boehlefeld, Renner, Otto, Boisselle & Sklar, LLP, Nineteenth Floor, 1621 Euclid Avenue, Cleveland, OH, 44115-2191, US

(21) Appl. No.: 10/346,288

(22) Filed: Jan. 17, 2003

Related U.S. Application Data
(60) Provisional application No. 60/349,907, filed on Jan. 18, 2002.

(51) Int. Cl. H01L 23/48

(52) U.S. Cl. 257/774

(57) ABSTRACT

An anisotropically conductive structure for providing electrical interconnection between electronic components, and the process for making such anisotropically conductive structure. The anisotropically conductive structure includes a dielectric matrix having a substantially uniform thickness; an array of vias extending into or through the matrix; a plurality of conductive elements, wherein individual via contains at least one conductive element; a first adhesive layer adhered to the first major surface of the matrix; and optionally, a second adhesive layer adhered to the second major surface of the matrix.

### FIELD OF THE INVENTION

The present invention is directed to an anisotropically conductive polymeric film for providing electrical interconnection between electronic components, and the process for making such anisotropically conductive film. More particularly, the anisotropically conductive polymeric film of the present invention has electrical conductors formed in through holes or microindentations within a dielectric polymeric matrix.

### BACKGROUND OF THE INVENTION

Anisotropically conductive films are well known and have been used commercially in the electronics industry for some time. Such films generally comprise a sheet-like, dielectric carrier material that is loaded with conductive particles. The particle loading is kept low so that formation of electroconductive paths in the X- and Y-axis direction of the carrier material is avoided. The film is rendered conductive via the particles only in the Z-axis direction of the material.

Anisotropically conductive films provide a convenient and useful way to electrically connect electrode pads on separate circuits or between layers of a multiple layer circuit. An anisotropically conductive film allows conduction between opposing electrodes through the film, but does not allow conduction in the plane of the film. Thus, adjacent electrode pads meant to conduct independently can remain electrically isolated from each other while being bonded and electrically connected to partner electrodes on opposing circuits or circuit layers.

Anisotropically conductive films may be used in a variety of applications, such as the bonding of circuits and the bonding of components such as liquid crystal displays and surface mound devices. The most common anisotropically conductive films are random in nature, i.e., the conductive particles are randomly distributed throughout the adhesive carrier material. The electrical interconnections are influenced by the number of point contacts per unit area. Difficulties arise when higher density connections are desired. Higher density connections involve smaller spacings between electrodes as well as smaller electrode pads. Using randomly distributed conductive particles within an adhesive to connect such fine pitch circuits can lead to electrical shorts between adjacent electrodes. To overcome this problem, a lower loading volume of conductive particles in the adhesive is used. However, such lower loading volume often results in decreased reliability of the electrical connections due to the existence of fewer particles per connection, particularly when very small electrodes are used.

The present invention is directed to an anisotropically conductive structure having a predetermined pattern, or array of conductive elements. The spacing between the conductive elements as well as the density of the conductive elements can be customized for the particular circuit in which the anisotropically conductive structure is to be used. Using the method of making anisotropically conductive structures of the present invention, symmetrical and asymmetrical arrays of precision microstructured vias filled with conductive elements are produced.

### SUMMARY OF THE INVENTION

The present invention provides an anisotropically conductive structure comprising: a dielectric matrix having a substantially uniform thickness and having a first major surface and a second major surface; an array of vias extending from the first major surface to the second major surface of the matrix, wherein the opening of the via at the first major surface is larger than the opening of the via at the second major surface; a plurality of conductive elements, wherein the individual via contains at least one conductive element; a first adhesive layer adhered to the first major surface of the matrix; and a second adhesive layer adhered to the second major surface of the matrix.

The present invention further provides an anisotropically conductive structure comprising: a dielectric matrix having a substantially uniform thickness and having a first major surface and a second major surface; an array of vias extending from the first major surface into the thickness of the matrix forming an array of microindentations of uniform depth in the matrix; a plurality of conductive elements, wherein the individual via contains at least one conductive element; a first adhesive layer adhered to the first major surface of the matrix; and a second adhesive layer adhered to the second major surface of the matrix.

According to a method of the present invention, the anisotropically conductive structure can be made by a comprising the steps of: providing a dielectric film having a first major surface and a second major surface; forming an array of tapered vias extending from the first major surface of the dielectric film into the thickness of the dielectric film with an embossing device having an array of tapered projections projecting therefrom; filling individual vias with at least one conductive element; and applying an adhesive layer to one or both sides of the dielectric layer. The adhesive layer may be releasably adhered to a release liner.

According to another method of the present invention, the anisotropically conductive structure can be made by a comprising the steps of: providing a multilayer structure comprising a dielectric film having a first major surface and a second major surface, and a carrier layer having an inner surface and an outer surface, wherein the inner surface is releasably adhered to the second major surface of the dielectric film; forming an array of tapered vias extending from the first major surface of the dielectric film to the second major surface of the dielectric film with an embossing device having an array of tapered projections projecting therefrom; filling individual vias with at least one conductive element; and removing the carrier layer. An adhesive layer is then laminated to one or both sides of the dielectric layer. The adhesive layer may be releasably adhered to a release liner.

In one embodiment of the present invention, preselected vias of the array are filled by jetting conductive elements into the vias.

### BRIEF DESCRIPTION OF THE DRAWINGS

FIG. 1 is a cross-sectional view of one embodiment of the anisotropically conductive structure of the present invention in which through holes are formed in the dielectric matrix.

FIG. 2 is a cross-sectional view of an alternative embodiment of the anisotropically conductive structure of the present invention in which microindentations are formed in the dielectric matrix.

FIG. 3 is a top view of a dielectric matrix sheet according to the present invention, the sheet having an array of microsized vias extending through the thickness (i.e., the z-direction) of the sheet.

FIG. 4 is side cross-sectional view of the dielectric matrix sheet.

FIG. 4A is a schematic view showing the geometry of one of the vias in the sheet shown in FIGS. 3 and 4.

FIGS. 4B-4J are schematic views showing alternative embodiments of geometries of the via according to the present invention.

FIGS. 5A-5K are schematic views of steps of a method of making the dielectric sheet according to the present invention.

FIG. 5L is a schematic view of the dielectric sheet of the present invention in roll form.

FIG. 5H is a schematic view of the dielectric sheet of the present invention cut into sections of desired length.

FIG. 6 is a schematic view of an apparatus for making the dielectric sheet according to the present invention.

FIG. 7 is a schematic view of another apparatus for making the dielectric sheet according to the present invention.

FIGS. 8A and 8B are schematic views of the dielectric sheet wherein the vias are made electrically conductive according to the present invention.

FIGS. 9A and 9B are cross-sectional views of the anisotropically conductive structure of the present invention in an electronic circuit.

### DETAILED DESCRIPTION OF THE INVENTION

Anisotropically Conductive Structure:

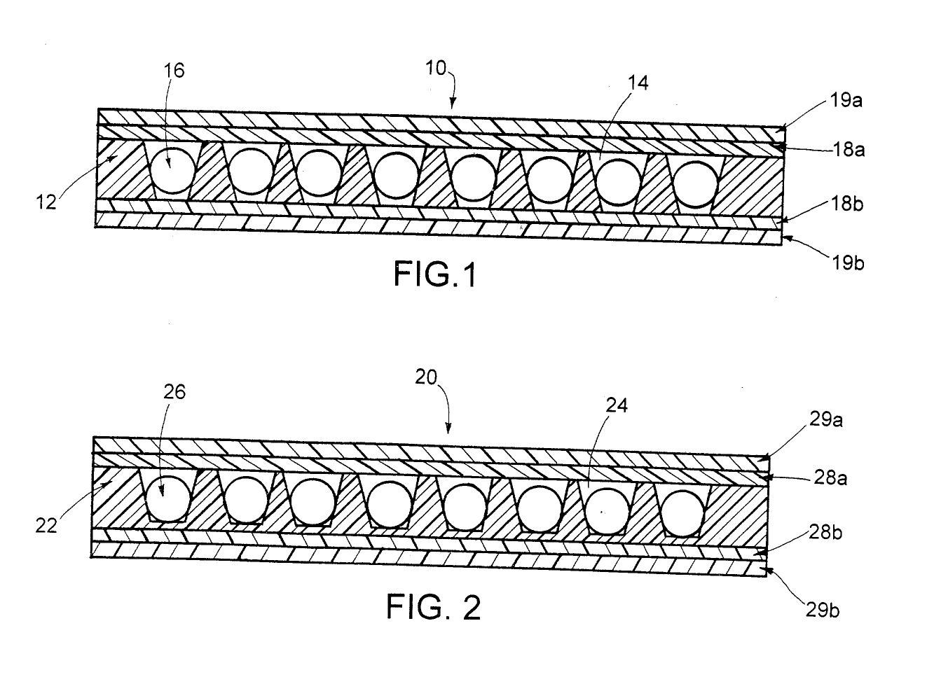

The anisotropically conductive structure of the present invention comprises a dielectric matrix having a plurality of vias formed in an array therein. The vias are filled with one or more conductive elements. FIG. 1 shows a cross-sectional view of one embodiment of the anisotropically conductive structure 10 of the present invention. Dielectric matrix 12 has a plurality of vias 14 formed therein. The vias 14 extend from the top surface of the dielectric matrix 12 to the bottom surface of the dielectric matrix, thus forming through holes in the dielectric matrix. The vias may be arranged in a symmetrical pattern or an asymmetrical pattern. Within the individual vias 14 is a conductive particle 16. An adhesive layer (18a and 18b) is adhered to each of the top and bottom surfaces of the dielectric matrix 12. Adhesive layers 18a and 18b may be of the same composition and thickness, or may be of different compositions and/or thicknesses. A release layer (19a and 19b) is releasably adhered to the outer surface of each of the adhesive layers 18a and 18b.

In another embodiment not shown, an adhesive layer 18a is adhered to the top surface of dielectric matrix 12, and the bottom surface of dielectric matrix 12 is without a separate adhesive layer. A release layer 10 a may be releasably adhered to the outer surface of adhesive layer 18a.

In yet another embodiment, adhesive layer 18a and/or 18b comprise a multilayer adhesive.

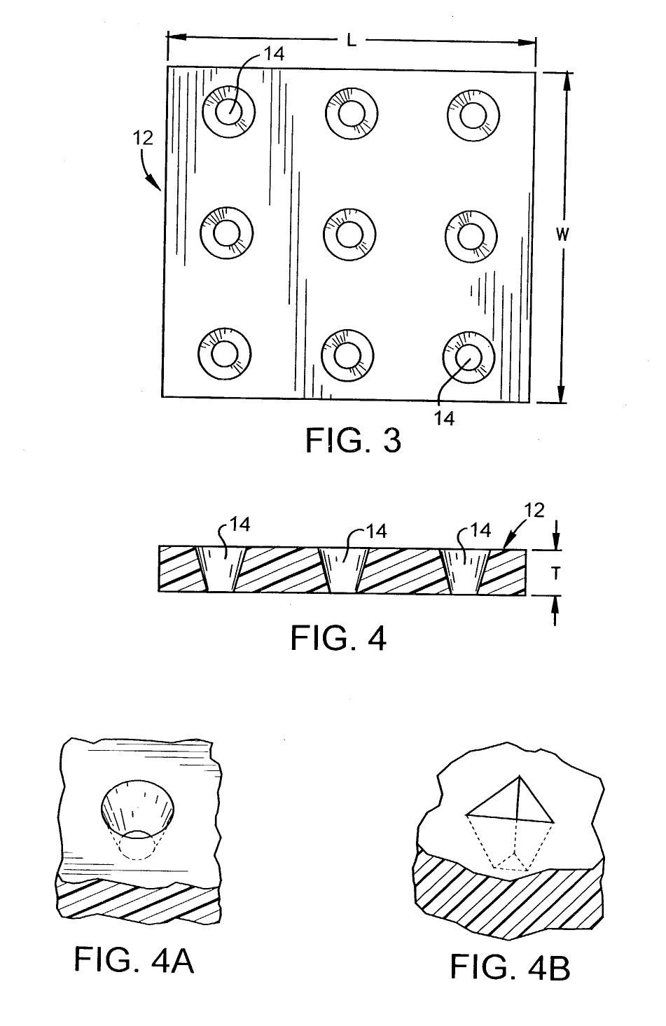

FIG. 2 shows a cross-sectional view of an alternative embodiment of the anisotropically conductive structure 20 of the present invention. This embodiment is substantially similar to that shown in FIG. 1, with the exception that the vias 24 do not extend the entire way through the thickness of the dielectric matrix 22. Rather, vias 24 form microindentations in the dielectric matrix 22. Each microindentation may contain a conductive particle 26. In one embodiment, the microindentation extends through the thickness of the dielectric matrix 22 to within about 1 micron to 5 microns of the entire thickness of the dielectric matrix. Adhesive layers 28a and 28b are adhered to the top and bottom surfaces, respectively, of the dielectric layer 22. Release layers 29a and 29b are releasably adhered to the outer surface of each of adhesive layers 28a and 28b, respectively.

As used herein, the term “via” refers to both a through-hole and a microindentation in the dielectric matrix. Each via may contain any number of discrete conductive particles. Preferably, each via contains a single conductive particle. The vias may be arranged in any ordered two-dimensional pattern. The particle sites in an array need not be the same size and the number of particles per via may vary from site to site. When such is the case, the desired number of particles varies from site to site in an ordered manner. For example, the vias may be arranged in a square array where the desired number of particles per via alternates between two and four adjacent vias. The desired spacing between vias will depend on the electrode patterns on the circuits to be bonded. For example, in fine pitch applications, the center-to-center spacing between vias may be in the range of less than 5μm or 10μm. The via spacing is limited only by the electrode pattern, the desired number of particles per via, and the average particle size.

Each conductive particle or element is individually deposited into the via so that there is no more than one conductive particle or element in any given column perpendicular to the dielectric layer. In other words, the conductive particles or elements are not stacked within an individual via. This ensures that each conductive pathway between circuit electrodes is through a single particle. In one embodiment, each via contains a conductive element or particle. In another embodiment, a predetermined pattern of vias is filled with conductive elements or particles, so that some of the vias of the dielectric layer are filled, and some remain unfilled.

Dielectric Matrix:

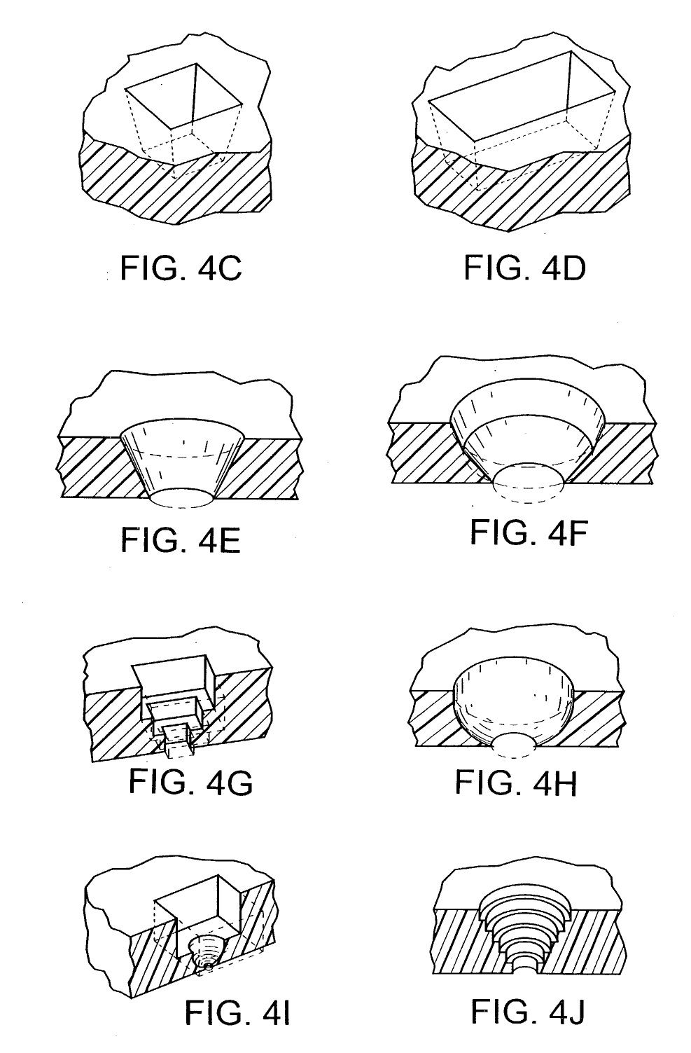

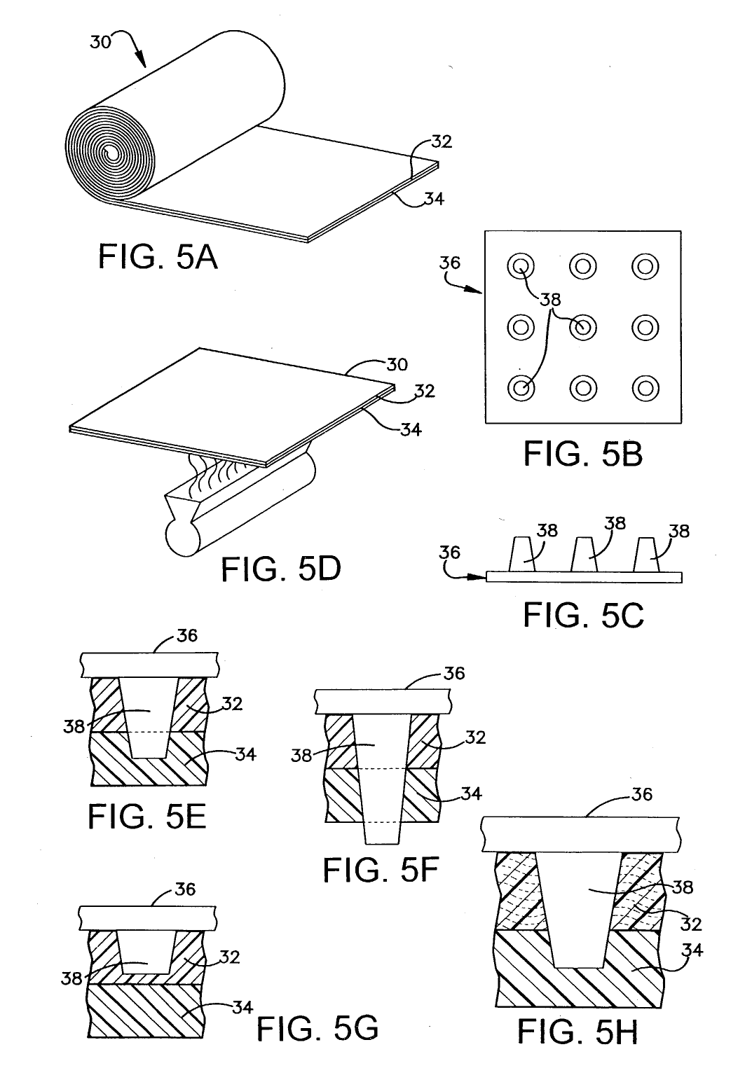

The dielectric matrix can be described by referring to FIGS. 3 and 4. The dielectric matrix is formed from a sheet 12 of polymeric material. Sheet 12 can be a single layer of a thermoplastic material or a laminate of different thermoplastic layers compatible with its intended application. For example, the thermoplastic material may comprise polyolefins, both linear and branched, polyamides, polyimides, polystyrenes, polyurethanes, polysulfones, polysulfides, polyesters, polyvinyls, polyvinyl chloride, polyvinyl acetals, polycarbonates, polyketones, polyethers, phenoxy resins and acrylic polymers and copolymers. The dielectric material may also comprise an elastomeric material, such as for example, silicone, fluoroelastomer, urethane, acrylic, butyl rubber, Kraton™ rubber and latex.

The sheet 12 can have a generally planar geometry having, for example, a width W, a length L, and a thickness T. The width W can be constant across the sheet's length and can be of a dimension compatible with the equipment used to incorporate the sheet 12 into the desired final product. The length L can be a predetermined distance in the same general range as the width W or can be substantially longer so that the sheet 12 resembles a continuous web. In one embodiment, the thickness T is in the range of about 5 to about 50 microns. In another embodiment, the thickness T is in the range of about ten to about thirty microns, and in another embodiment, about fifteen to about twenty-five microns. The thickness T can be constant across the sheet's length and/or width.

The array-arrangement of the vias 14 can be in aligned rows and columns, staggered rows and columns, and/or changing rows and columns. Additionally or alternatively, the spacing between the vias 14 can be the same, can change proportionally, and/or can be different. Also, the vias 14 can be asymmetrically arranged so that an array pattern or spacing sequence is not apparent. In one embodiment, the spacing between adjacent vias 14 (center-to-center) is in the range of about 5 to 300 microns. In another embodiment, the spacing between adjacent vias 14 is in the range of about 5 to 100 microns, and in another embodiment, about 5 to 40 microns. In yet another embodiment, the spacing between adjacent vias 14 is in the range of about 40 to 100 microns.

Referring now to FIG. 4A, the geometry of one of the vias 14 is schematically shown. The illustrated via 14 has a frustoconical shape having an axial dimension A equal to the thickness T of the sheet 12, a first (top) circular axial end and second (bottom) circular axial end. The area of the top end is greater than the area of the bottom end, so that the via 14 tapers downwardly.

The tapering shape of the via 14 accommodates certain methods and/or apparatus for making the sheet 12. In other words, one axial end will define the maximum cross-sectional area of the via 14 and the other axial end will define the minimum cross-sectional area of the via 14. In many cases, the dominating dimension (e.g., the diameter of a circular end, the length of a rectangular end, and the height/base of a triangular end) defining the maximum cross-sectional axial end will be less than the thickness T of the sheet 12 and thus less than the axial dimension of the via 14. In one embodiment, the dominating dimension of the larger axial end will be in the range of about 2 to 150 microns. In another embodiment, the dominating dimension of the larger axial end will be in the range of about 5 to 20 microns, and in yet another embodiment, from about 10 to about 15 microns. In one embodiment, the dominating dimension of the smaller axial end will be in the range of about 2 to about 50 microns and, in another embodiment, about 2 to about 10 microns. In yet another embodiment, the dominating dimension of the smaller axial end will be in the range of about 3 to about 5 microns. In the frustoconical shape shown in FIGS. 3 and 4, for example, the top axial end could have a diameter of about 13 microns and/or the bottom axial end could

Other via geometries are possible with and contemplated by the present invention. For example, as shown in FIGS. 4B-4J, the axial ends instead can be triangular (FIG. 4B), square (FIG. 4C), rectangular (FIG. 4D), oval (FIG. 4E). The walls connecting the axial ends can have a constant slope (FIGS. 4A-4E) or can have a changing slope to provide a stepped or semi-spherical shape (FIGS. 4F and 4G). The geometry of the cross-sectional shape can remain the same (FIGS. 4A-4H and 4J) or can change at a predetermined depth in the via (FIG. 41).

Conductive Particles:

The conductive particles 16 may be made of any conductive material or of any material having a contiguous conductive coating. Depending on the application, the conductive particles may be deformable and made of either a deformable metal or of a deformable core particle coated with a contiguous conductive coating. Examples of conductive metals useful in the present invention include tin, lead, bismuth, zinc, indium, aluminum, copper, silver, gold, nickel, cobalt, iron, palladium, tungsten, gallium and their alloys, and mixtures thereof. The conductivity of metal particles may be increased by coating the particles with a higher conductivity metal such as copper, gold, silver, nickel, cobalt or platinum by, for example, electroplating. The conductive particles may also comprise metalized glass, metalized polymers and/or metalized ceramics. While spherical particles are preferred, particles of any shape may be used. In one embodiment, the conductive particles have an average diameter within the range of about 2 to about 150, and in another embodiment, within the range of about 2 to about 50 microns. The conductive particles have a narrow size distribution. In one embodiment, the coefficient of variation (CV) is less than 4%.

In one embodiment, the conductive element used to fill the vias comprises conductive particles dispersed in a binder. Examples of useful binders include acrylate polymers, ethylene-acrylate copolymers, ethylene-acrylic acid copolymers, ethylene-vinyl acetate copolymers, polyethylene, ethylene-propylene copolymers, acrylonitrile-butadiene copolymer, styrene-butadiene block copolymers, styrene-butadiene-styrene block copolymers, carboxylated styrene-ethylene-butadiene-styrene block copolymers, epoxidized styrene-ethylene-butadiene-styrene block copolymers, styrene-isoprene block copolymers, polybutadiene, ethylene-styrene-butylene block copolymers, polyvinyl butyral, polyvinyl formal, phenoxy resins, polyesters, polyurethanes, polyamides, polyvinyl acetal, polyvinyl ethers, polysulfones, nitrile-butadiene rubber, styrene-butadiene rubber, chloroprene rubbers, cyanate ester polymers, epoxy resins, silicone resins, phenol resins, and blends of thereof.

Adhesives:

A wide range of adhesives may be used as the adhesive layers 18a and 18b of the anisotropically conductive structure of the present invention. Useful adhesives include pressure sensitive adhesives, thermoplastic adhesives or thermoset adhesives, e.g. a B-stage epoxy. Where the adhesive is tacky at ambient temperature, it is desirable to use a release liner to cover the adhesive. Examples of useful adhesives include acrylate polymers, ethylene-acrylate copolymers, ethylene-acrylic acid copolymers, ethylene-vinyl acetate copolymers, polyethylene, ethylene-propylene copolymers, acrylonitrile-butadiene copolymers, styrene-butadiene block copolymers, styrene-butadiene-styrene block copolymers, carboxylated styrene-ethylene-butadiene-styrene block copolymers, epoxidized styrene-ethylene-butadiene-styrene block copolymers, styrene-isoprene block copolymers, polybutadiene, ethylene-styrene-butylene block copolymers, polyvinyl butyral, polyvinyl formal, phenoxy resins, polyesters, polyurethanes, polyamides, polyvinyl acetal, polyvinyl ethers, polysulfones, nitrile-butadiene rubber, styrene-buradiene rubber, chloroprene rubbers, cyanate ester polymers, epoxy resins, silicone resins, phenol resins, photocurable resins, anaerobic resins and the like. These adhesive resins may be used independently or in blends of two or more. A particularly useful adhesive is radiation curable adhesive, such as that described in copending application Ser. No. 09/594,229, which is hereby incorporated by reference.

If necessary, a curing agent and/or a curing catalyst may be used to increase the molecular weight of the non-conductive adhesive, either by cross-linking or polymerization. The curing mechanism can be initiated thermally or by radiation, such as by UV radiation or electron beam radiation. Examples of curing agents and curing catalysts that may be used in the adhesive include those that conventionally have been used in conjunction with the adhesive resins described hereinabove. The method of curing the adhesive must be compatible with the apparatus used to bond the electronic circuit.

In one embodiment of the present invention, the adhesive 18 is coated onto a release liner 19 and then transferred to the anisotropically conductive film. Prior to use, the release liner 19 is removed.

In one embodiment of the present invention, adhesive 18 comprises a multilayer adhesive applied onto the anisotropically conductive film. Alternatively, a multilayer adhesive 18 is applied onto release liner 19, and then transferred to the anisotropically conductive film.

Microreplication Process:

The dielectric matrix having vias formed therein can be made by an embossing process. Considering now the dielectric matrix material in greater detail, for purposes of the present invention, two temperature reference points are used: T_{g} and Tₑ. T_{g} is defined as the glass transition temperature, at which plastic material will change from the glassy state to the rubbery state. It may comprise a range before the material may actually flow. Tₑ is defined as the embossing or flow temperature where the material flows enough to be permanently deformed by the embossing process, and will, upon cooling, retain form and shape that matches or has a controlled variation (e.g. with shrinkage) of the embossed shape. Because Tₑ will vary from material to material and also will depend on the thickness of the film material and the nature of the dynamics of the embossing apparatus used, the exact Tₑ temperature is related to conditions including the embossing pressure(s); the temperature input of the embossing apparatus and the speed of the embossing apparatus, as well as the extent of both the heating and cooling sections in the reaction zone.

The embossing temperature must be high enough to exceed the glass transition temperature T_{g}, so that adequate flow of the material can be achieved to provide highly accurate embossing of the film by the embossing apparatus. Numerous thermoplastic materials may be considered as polymeric materials to provide anisotropically conductive film. However, not all can be embossed on a continuous basis. Applicants have experience with a variety of thermoplastic materials to be used in continuous embossing under pressure at elevated temperatures. These materials include thermoplastics of a relatively low glass transition temperature (up to 302° F./150° C.), as well as materials of a higher glass transition temperature (above 302° F./150° C.).

Typical lower glass transition temperature (i.e. with glass transition temperatures up to 302° F./150° C.) include materials used for example to emboss cube corner sheeting, such as vinyl, polymethyl methacrylate, low T_{g} polycarbonate, polyurethane, and acrylonitrile butadiene styrene (ABS). The glass transition T_{g} temperatures for such materials are 158° F., 212° F., 302° F, and 140° to 212° F. (70° C., 100° C., 150° C., and 60° to 100° C).

Higher glass transition temperature thermoplastic materials (i.e. with glass transition temperatures above 302° F./150° C.) which applicants have found suitable for embossing precision microvias, are disclosed in previously identified co-pending patent application U.S. Ser. No. 09/776,281, filed Feb. 2, 2001. These polymers include polysulfone, polyacrylate, cyclo-olefinic copolymer, high T_{g} polycarbonate, and polyether imide.

A table of exemplary thermoplastic materials, and their glass transition temperatures, appears below as Table I:

TABLE I

| Symbol | Polymer Chemical Name | T_{g} ° C. | T_{g} ° F. |
|---|---|---|---|
| PVC | Polyvinyl Chloride | 70 | 158 |
| Phenoxy | Phenoxy PKHH | 95 | 203 |
| PMMA | Polymethyl methacrylate | 100 | 212 |
| BPA-PC | Bisphenol-A Polycarbonate | 150 | 302 |
| COC | Cyclo-olefinic copolymer | 163 | 325 |
| Polysulfone | Polysulfone | 190 | 374 |
| Polyacrylate | Polyacrylate | 210 | 410 |
| PC | High T_{g} polycarbonate | 260 | 500 |
| PEIPI | Polyether imide | 260 | 500 |
| Polyurethane | Polyurethane | varies | varies |
| ABS | Acrylonitrile Butadiene Styrene | 60-100 | 140-212 |

In general, a certain fluidity of the embossed material is required during the embossing process. Such fluidity can be achieved by increasing the embossing temperature higher than the glass transition temperature or melting temperature of the embossing material. Applicants have observed as a rule of thumb that for good fluidity of the molten thermoplastic material in the reaction (embossing) zone, the embossing temperature Tₑ should be at least 50° F. (10° C.), and advantageously between 100° F. to 150° F. (38° C. to 66° C.), above the glass transition temperature or melting temperature of the thermoplastic layer.

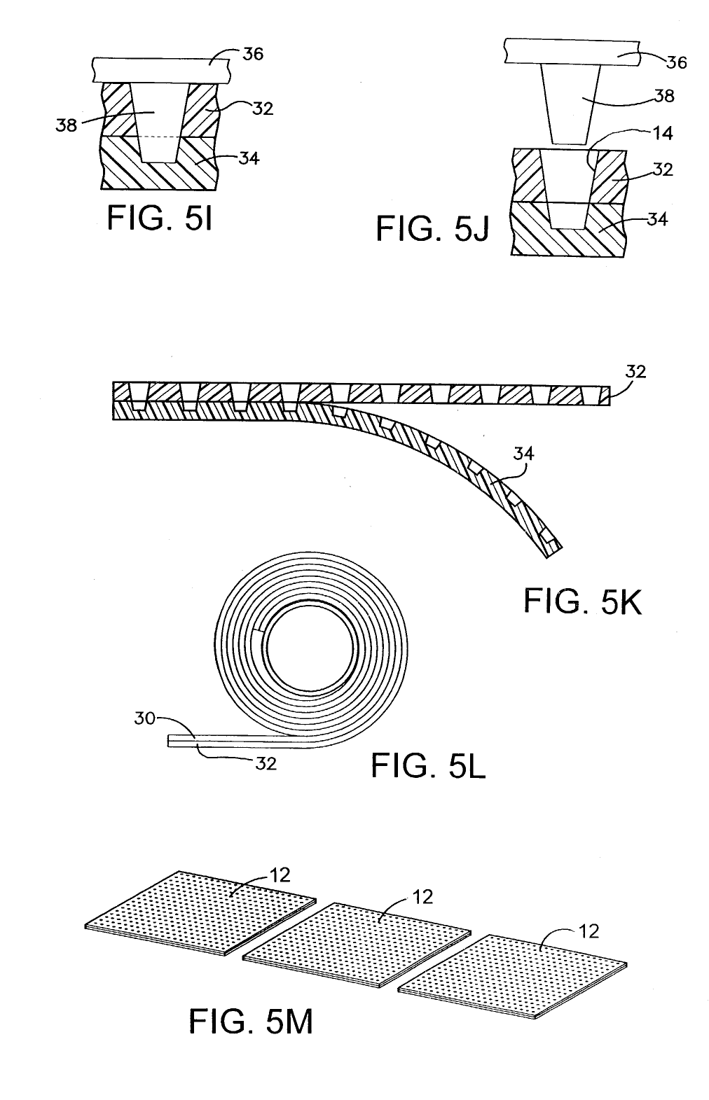

Referring now to FIGS. 5A-5J, the steps of one embodiment of the method for making the embossed dielectric sheet are schematically shown. In this method, a web 30 is provided having at least a thermoplastic layer 32 and a plastic carrier layer 34 (FIG. 5A).

In one embodiment, the plastic carrier layer 34 is selected from materials having a melting temperature (or glass transition temperature of the material if the material does not have a melting temperature) substantially greater than the glass transition temperature (or melting temperature) of the thermoplastic layer 32. The ability of the carrier layer 34 to support the thermoplastic layer 32 during certain method steps can also be taken into consideration when choosing a carrier material. Suitable carrier materials include thermoplastic, and thermosetting materials compatible with the manufacturing method. Examples of particularly suitable carrier materials for carrier layer 34 include polyolefins; polyurethanes; polyesters such as, for example, PET; and PTFE.

A tool 36 is provided having a series of projections 38 sized, shaped and arranged to correspond to the desired array of vias 14 on the sheet 12. (FIGS. 5B and 5C). Thus, to make the sheet 12 illustrated in FIGS. 3 and 4, the projections 38 would have a frustoconical shape and would be arranged in aligned rows and columns. It may be noted, however, that the distal end portions of the projections may be required to represent an extension of the smaller axial end of the via 14 as it may extend past the distance defined bottom surface of the sheet 12. In one embodiment, the projections extend into the thermoplastic film (or thermoplastic film plus carrier layer) to a depth of less than 0.040 inch (1016 microns), and in another embodiment, less than 0.010 inch (254 microns).

The tool 36 can be made of any suitable material, such as nickel, that will withstand the subsequent method steps. For example, the tool 36 must withstand the method steps of heating and cooling of the tool 36. Accordingly, the dimensions of the tool 36 may affect the heating and cooling energy necessary to reach the required temperature gradients. A thin tool (about 0.010 inches (0.254 mm) to about 0.030 inches (0.762 mm)) will facilitate rapid heating and cooling, while a thicker tool will require longer periods of time for heating and cooling.

The tool 36 can be manufactured by known techniques to create micropatterns in rigid substrates, such as photolithography, deep reaction ion etching, plasma etching, reactive ion etching, deep x-ray lithography, electron beam lithography, or ion milling. In one embodiment, a female master is electroformed and used to create several male patterns that are assembled together to form the tool 36. Additional details of making the tool 36 can be found in U.S. Pat. Nos. 4,478,769 and 5,156,863, which are hereby incorporated by reference herein.

In the method of the present invention, the web 30 is heated so that thermoplastic layer 32 is sufficiently flowable. (FIG. 5D.) In many cases, this will require that the material of layer 32 is heated to at least its glass transition temperature, T_{g} or Tₘ. In one embodiment of the method of the present invention, the material of thermoplastic layer 32 is heated to a temperature above its T_{g} to obtain a sufficiently flowable material. Once the thermoplastic layer 32 is sufficiently heated, the tool 36 is brought into contact with the web 30 so that the projections 38 extend through the thermoplastic layer 32 to the carrier layer 34. (FIGS. 5E and 5F.) The resinous material of the layer 32 is sufficiently flowable to mold around the projections 38. (FIG. 5H.) Thus, the projections 38 do not puncture or pierce the thermoplastic layer 32 as would occur if a nail is hammered through a block of wood. Instead, the interaction between the thermoplastic layer 32 and the projections 38 more accurately duplicates what would occur if a nail is dipped into a bucket of water. The carrier layer, on the other hand, does not have to be “cleanly” embossed, since the carrier does not become a component of he final anisotropically conductive film. Hence, the projections 38 may punch into the carrier layer under pressure when the temperature of the carrier layer is below its T_{g}.

The distal end portions of the projections 38 can extend partially into the carrier layer 34 (FIG. 5E) or can extend entirely therethrough (FIG. 5F). Alternatively, projections 38 can extend partially into the thermoplastic layer 32 without penetrating carrier layer 34 (FIG. 5G). The carrier layer acts as an “anvil” during the process of embossing through holes in the thermoplastic layer 32. It is noted that since the size and shape of the via 14 can change depending upon the penetration of the projection 38, some type of depth registration may be required. This registration can be accomplished by measuring the vertical position of the tool 36 (FIGS. 5E, 5F and 5G) and/or by sensing the penetration of the projections 38 through the carrier layer 34 (FIG. 5F). The shape of the via 14 is dependent upon the geometry of the projection 38, the thickness of the thermoplastic film 32, and the temperature and pressure used in the embossing step.

In another embodiment, the thermoplastic layer 32 is embossed without the use of a carrier layer. When the projections 38 partially extend into the thermoplastic layer 32 to form microindentations, a carrier layer may not be required to maintain the structural integrity of the thermoplastic layer 32. The process for forming microindentations is substantially similar to that described above for forming through holes in the thermoplastic layer.

With the projections 38 still extending to or through the carrier layer 34, if present, the web 30 is cooled so that thermoplastic material solidifies around the projections. (FIG. 51.) After sufficient solidification, the material surrounding the projections 38 will no longer depend upon the tool 36 for shape-defining purposes. The tool 36 is then stripped from the web 30, leaving behind the vias 14. (FIG. 5J.)

The forming steps of the present invention are believed to provide essentially exact sized surfaces and very precise inter-via patterns. The molded via-defining surfaces are formed without distortion thereby allowing enhanced smoothness of flat and curved regions of the via geometry. Also, with via shapes incorporating polygonal geometries (see e.g., FIGS. 4B-4D, 4G and/or 4I, the via-defining surfaces have increased angular accuracy and sharp corners can be incisively obtained.

The via-defining surfaces of the present invention are believed to be structurally superior (and structurally different) than vias formed by conventional methods, such as curing, ablation, stamping, and punching techniques. In a curing process, for example, the molded material must undergo a significant chemical change thereby making final geometries (dimensions and surface profiles) difficult to predict in a micro-tolerance situation, especially via-to-via. An ablation process (such as laser ablation) involves the vaporization of a via-shaped piece of material, a stamping process requires the compaction of a via-shaped piece of material into surrounding regions, and a punching process requires the removal of a via-shaped piece of material. To the extent that sizing-specification and/or pattern-precision could be obtained with an ablation, stamping, and/or punching process, the profile of the surfaces would be difficult, if not impossible, to maintain. Accordingly, the present invention is believed to provide via-defining surfaces which have closer size-exactness, enhanced pattern precision, increased angle accuracy, and/or greater surface smoothness than via-defining surfaces formed by prior art methods.

Once the tool 36 has been stripped from the web 30, the carrier layer 34 can be removed (e.g., peeled) from the thermoplastic layer 32 (FIG. 5K). If the web 30 reflects the desired size of the sheet 12, then the production of the sheet 12 is complete and it is ready for further processing, assembly, and/or finishing. If the web 30 was of a continuous length, the product can be wound onto a roll (FIG. 5L) for later sectioning into desired lengths. Alternatively, the web 30 can be cut into sections of the desired sheet dimensions (FIG. 5M). It should be noted that the peeling step can be performed before, during or after the winding and/or cutting steps.

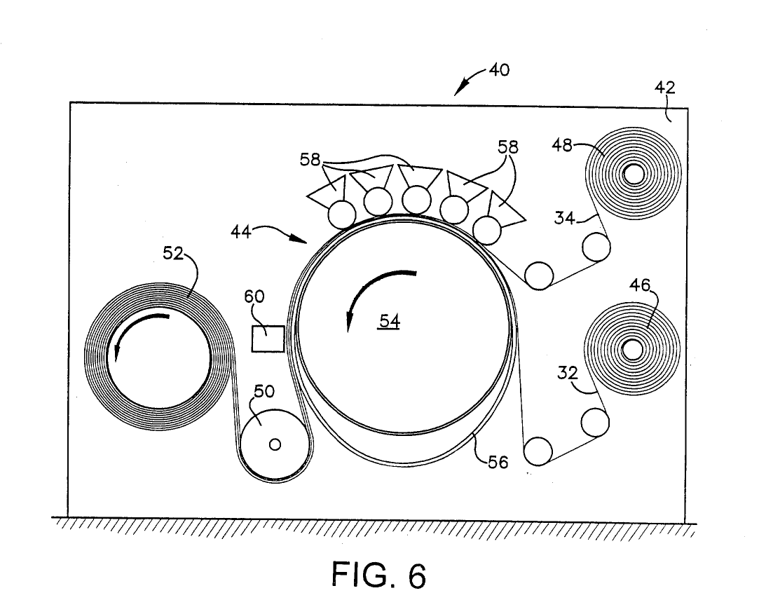

Referring now to FIG. 6, an apparatus 40 is shown for making the sheet 12 according to the present invention. The illustrated apparatus 40 includes a frame 42 with an embossing device 44 mounted thereon for performing the heating, projection-engaging, and cooling steps. Supply reels 46 and 48, a stripper reel 50, and a take-up reel 52 are also mounted on the frame 42, along with appropriately placed guide rollers (shown but not specifically numbered).

In the illustrated orientation, the supply reels 46 and 48 are positioned on the right side of the frame 42 and the stripper reel 50 and the take-up reel 52 are positioned on the left side of the frame. The reel 46 supplies the thermoplastic layer 32 and the reel 48 supplies the carrier layer 34. The layers 32 and 34 pass from their respective supply reels, over guide rollers, and are superimposed before or at the embossing device 44 to form the web 30. After passing through the embossing device 44 in a counter-clockwise direction, the embossed web 30 is removed from the device 44 by the stripper reel 50 and the removed material is wound on the take-up reel 52.

In the illustrated embodiment, the carrier layer 34 is removed from the thermoplastic layer 32 after winding. However, the apparatus 40 can be modified to include a pre-winding removal device if desired. Also, the take-up reel 52 can be replaced or complemented by a cutting device that divides the embossed web 30 into sections of desired dimensions.

The embossing device 44 includes a conveyor that incorporates the tool 36. Specifically, the conveyor comprises a wheel 54 and a belt 56 that is driven thereby. The embossing device 44 also includes pressure-applying rollers 58.

In the illustrated apparatus 40, the wheel 54 functions both as part of the conveyor and as the heating station for the web. Wheel 54 can be heated by, for, example, circulation of hot oil through an internal spiral tube. A chain or other suitable drive (not shown) is used to rotate the wheel 54 at a certain speed in the appropriate direction that, in the illustrated embodiment, is counter-clockwise. The wheel 54 is used to both heat the web 30 and to advance the belt 56 at a predetermined linear velocity.

The belt 56 can be an endless metal belt that incorporates the tool 36 with the via-forming projections 38 facing radially outwardly. When traveling over upper circumferential portions of the wheel 54, the belt 56 contacts the wheel 54 as it passes between the wheel 54 and the pressure-applying rollers 58.

The pressure-applying rollers 58 are positioned to urge the web 30 towards the belt 56 whereby the projections 38 can extend through the thermoplastic layer 32 and through or to the carrier layer 34, if present. The rollers 58 are positioned upstream on the wheel 54 so that the web 30 will be heated so that the thermoplastic layer 32 is sufficiently flowable prior to contact with the tool 36. The wheel 54 is internally heated so that as belt 56 passes thereover, the temperature of the embossing pattern at that portion of the tool 36 is raised sufficiently so that thermoplastic layer 32 is heated to a temperature above its T_{g}, but not sufficiently high as to exceed the T_{g} of the carrier layer 34. For an acrylic thermoplastic layer 32 and polyester carrier layer 34, a suitable temperature for the heated wheel 54 is in the range of from 425° F. to 475° F., and preferably about 450° F.

The number and/or spacing of the rollers 58 can be selected based on the web material, the thermoplastic material and/or the desired micro-sized architecture. (These factors can also be considered when setting the pressure to be applied by the rollers 58.) In many cases, three to five rollers spaced sequentially around about 180° of the wheel 54 will be suitable. The carrier layer serves to maintain the thermoplastic layer 32 under pressure against the belt 56 while traveling around the heating and cooling stations, and while traveling the distance between them, thus assuming conformity of the thermoplastic layer 32 with the precision pattern of the belt 56 during the change in temperature gradient as the web drops below the T_{g} of the material. Additionally, the carrier layer acts as a carrier for the web in its weak “molten” state and prevents the web from adhering to the pressure rollers 58 as the web is heated above the T_{g}.

The web-cooling station 60 is positioned downstream of the pressure-applying rollers 58 and upstream of the point where the web 30 is removed from the embossing device 40 by the stripper reel 50. The cooling station 60 can be any suitable cooling means, such as a cooling knife or roller, which lowers the temperature of the web 30 so that the thermoplastic layer 32 is sufficiently solid prior to the web 30 being stripped from the belt 56. In this manner, the web 30 is maintained in engagement with the via-forming projections 38 until the thermoplastic layer 32 solidifies.

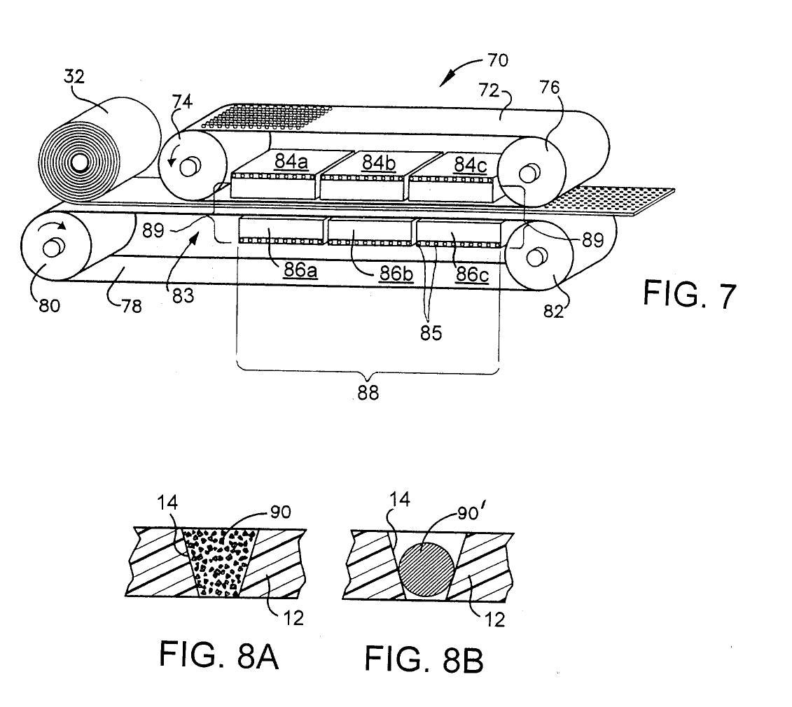

Referring now to FIG. 7, another apparatus 70 for making the embossed sheet 12 according to the present invention is shown. Apparatus 70 is a continuous press that includes a pair of upper rollers 74 and 76, and a pair of lower rollers 80 and 82. The upper roller 74 and the lower roller 80 may be oil heated. Typically the rollers are about 31.5 inches (80 cm) in diameter and extend for about 51 inches (130 cm). Around each pair of rollers is a belt, preferably made of nickel is preferred for microstructure formation.

An upper patterned belt 72 is mounted around the upper rollers 74, 76 and a lower plain surfaced belt 78 is mounted around the lower rollers 80, 82. The direction of rotation of the drums, and thus bands 72 and 78, is shown by the curved arrows. Heat and pressure are applied in a portion of the press referred to as the reaction zone 88, also defined by the brackets 89. Within the reaction zone are means for applying pressure and heat, such as three upper matched pressure sections 84a, 84b, 84c and three lower matched pressure sections 86a, 86b, 86c. Each section is about 39 inches (80 cm) wide and approximately 51 inches (130 cm) long. Heat and pressure may be applied by other means as is well known by those skilled in the press art. Also, it is understood that the dimensions set forth are for existing continuous presses, such as those manufactured by Hymmen; these dimensions may be changed if found desirable.

It is to be understood that each of the pressure sections may be heated or cooled; i.e., the temperature of each press section can be independently controlled. Thus, for example, the first two upstream pressure sections, upper sections 84a, 84b and the first two lower sections 86a, 86bmay be heated whereas the downstream sections 84c and 86c may be cooled or maintained as a relatively constant but lower temperature than the heated sections. It will be observed from FIG. 7 that each of the pressure sections may have provisions for circulating heating or cooling fluids therethrough, as represented by the circular openings 85.

The process for embossing the thermoplastic film to precise microstructure formation consists of feeding a thermoplastic film (or extrudate resin) into the press 70; heating the material to an embossing temperature Tₑ above the glass transition temperature T_{g} (e.g. about 100° F. to 150° F./38° C. to 66° C. above that glass transition temperature); applying pressure of about 150-700 psi/1.03-4.83 MPa (e.g. 250 psi/1.7 MPa) to the film; cooling the embossed film at the cooling station which can be maintained below ambient temperature (e.g. at about 72° F.; 22° C.) and maintaining a pressure of about 150-700 psi/1.03-4.83 MPa (e.g. about 250 psi/1.7 MPa) on the material during the cooling step.

For a given size embossing belt, and press machine, the embossing goal is to maximize production. Other things equal, the design that uses more of the belt's length is better. Length might be used for forming or for cooling. At the maximum running speed, these two minimum times (forming and cooling) occupy all the available length. The minimum time (length) required for forming may be less than, equal to, or greater than the minimum time (length) required for cooling. The present equipment permits some variation of these distances by virtue of the pressure plate arrangements. Additional pre-heating of the film before entry to the reaction zone, or post-reaction zone cooling also may be provided, depending on the materials used.

The reaction zone 88, 89 is formed between the lower run of the upper press band 72 and the upper run of the lower press band 78 in which the material sheet or web is fed, which is of a synthetic thermoplastic resin. The reaction zone pressure can be applied hydraulically to the inner surfaces of the endless press belts 72 and 78 by the opposing pressure plates 84a, 84b, 84c and 86a, 86b, 86c and is transferred from the belts to the film material fed therebetween. Reversing drums 74 and 80 arranged at the input side of the press are heated and, in turn, heat press belts 72 and 78. The heat is transmitted through the belts into the reaction zone where it is supplied to the film material. Similarly, the opposite reversing drums 76 and 82 may be arranged for additional cooling of the belts.

The pressing force is provided on the film material sheet in the reaction zone 88, 89 by a fluid pressure medium introduced into the space between the upper and lower pressure plates and the adjacent inside surfaces of the press belts located between the drums, which portions of the belts form the reaction zone. The space forming the so-called pressure chamber (exemplified for the lower belt as 83) is defined laterally by sliding seals. In order to avoid contamination of the film, desirably compressed air or other gases (as opposed to liquids) are used as the pressure medium in the pressure chamber of the reaction zone.

In the isobaric double band presses of Hymmen GmbH, in order to seal the highly pressurized air, the press includes cushion seals formed with highly smooth surfaces on the double bands. These provide a sliding seal to contain pressures of hundreds of pounds per square inch. In the case of a patterned belt 72, the sealing surface is the opposite face of the belt from that containing the precision microstructure pattern. A very smooth surface finish is required that may be provided for example using a polished chrome surface of a stainless steel band. In the case of the Hymmen isobaric press, a surface finish of 0.00008-0.00016 inches (2-4 micron) R_{z} is required, which is equivalent to 80-160 microinch rms in English units. Cf. American National Standards Institute, “Surface Finish”, ANSI B46.1. Surface treatment techniques such as polishing, electropolishing, superfinishing and liquid honing, can be used to provide the highly smooth surface finishes of belts 72, 78.

Examples of useful apparatus for making the embossed thermoplastic layer 32 of the present invention are described in copending applications, Ser. Nos. 09/596,240 filed Jun. 16, 2000, 09/781,756 filed Feb. 12, 2001, and 10/015,319 filed Dec. 12, 2001. These applications are owned by the assignee of the present invention and their entire disclosures are hereby incorporated by reference. In one embodiment of the continuous press apparatus useful in the present invention, a sliding seal is used. An example of such a seal is described in detail in U.S. Pat. No. 4,711,168, which is hereby incorporated by reference herein.

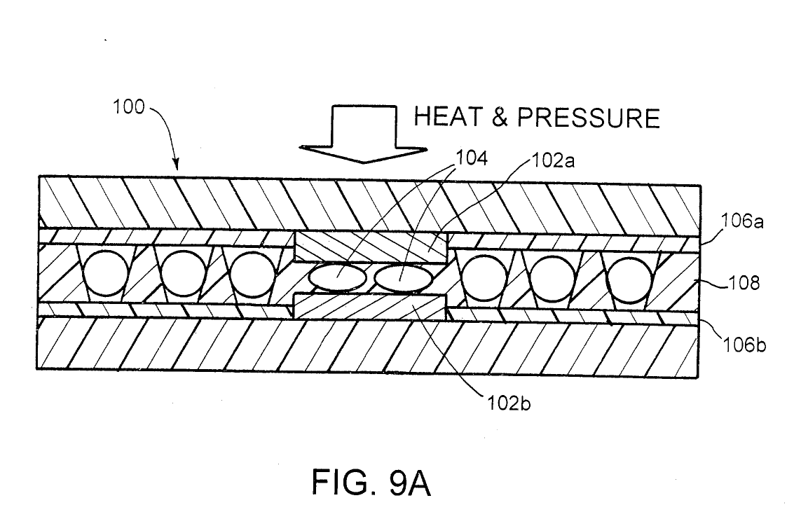

As was indicated above, the sheet 12 can be incorporated into a variety of electrical applications, each of which may require further processing and/or assembly. By way of example, electrically conductive particles 90 within a binder can be placed in the via 14 (FIG. 8A), and/or an electrically conductive object 90′ (e.g. a sphere having a diameter less than that of the circular top end and greater than that of the circular bottom end of a frustoconical shaped via) can be dropped into the via 14 (FIG. 8A).

In one embodiment, the microsized vias are made anisotropically conductive by depositing therein an electrically conductive particle or particles, such as metal-coated microspheres. In another embodiment, a conductive filler comprising conductive microspheres and a binder is spread over the embossed dielectric sheeting material having vias therethrough. When the vias are filled with a conductive filler comprising conductive elements within a binder, the binder is cured, either thermally or by radiation prior to lamination of the adhesive layer to the matrix. In one embodiment, the metal-coated microspheres in the filler can be forced into the vias, such as by the use of pressure to spread the conductive filler material on one side of the sheeting material, optionally assisted by a vacuum applied to the opposite side of the sheeting material. The excess conductive filler material is then removed, such as by wiping. Alternatively, the conductive particles are accurately dispensed into each of the microsized vias by a jetting method similar to ink-jet printing. If the vias comprise through holes, the jetting process may be optionally assisted by a vacuum applied to the opposite side of the dielectric sheeting material to facilitate entry of the dispensed conductive particles into the vias. The process of jetting the conductive particles may include the use of an ink-jet printhead to eject droplets of conductive material that coalesce and form a three-dimensional feature. British patent application GB 2,330,331 describes a process for conductive droplet deposition.

A release liner coated with, or laminated to, an adhesive layer can be applied to one or both sides of the dielectric sheet filled with conductive particles to form the anisotropically conductive structure. Prior to using the anisotropically conductive structure, the release liners are removed and the conductive matrix with the adhesive layers adhered thereto is positioned between opposing conductive pads of an electronic device. Pressure, or heat and pressure, are applied to the electronic device to deform the dielectric matrix and adhesive layer so that electrical contact with the conductive particles is made between the opposing conductive pads. The excess dielectric matrix material and adhesive are pushed into the voids surrounding the conductive particles within the vias.

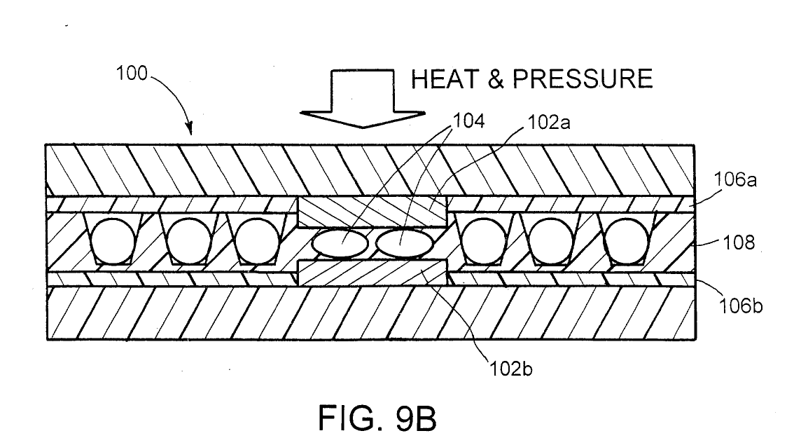

In one embodiment, illustrated in FIG. 9A, the anisotropically conductive structure of FIG. 1 is used to make electrical contact within an electronic device 100. In this embodiment, electronic device 100 has bump pads 102a and 102b. Heat and pressure is applied to the device so that electrical connection between bump pad 102a and 102b is made through conductive particles 104. The portions of adhesive layers 106a and 106b above and below conductive particles 104 have been pushed out of the areas above and below conductive particles 104, leaving conductive particles 104 in direct contact with bump pads 102a and 102b.

In another embodiment, illustrated in FIG. 9B, the anisotropically conductive structure of FIG. 2 is used to make electrical contact within an electronic device 100. In this embodiment, electronic device 100 has bump pads 102a and 102b. Heat and pressure is applied to the device so that electrical connection between bump pad 102a and 102b is made through conductive particles 104. The portions of adhesive layers 106a and 106b above and below conductive particles 104, as well as the portion of dielectric layer 108 beneath conductive particles 104, have been pushed out of the areas above and below conductive particles 104, leaving conductive particles 104 in direct contact with bump pads 102a and 102b.

Although the invention has been shown and described with respect to certain preferred embodiments, it is obvious that equivalent and obvious alterations and modifications will occur to others skilled in the art upon the reading and understanding of this specification. The present invention includes all such alterations and modifications and is limited only by the scope of the following claims.

1. An anisotropically conductive structure comprising:
a dielectric matrix having a substantially uniform thickness and having a first major surface and a second major surface;
an array of vias extending from the first major surface to the second major surface of the matrix, wherein the opening of the via at the first major surface is larger than the opening of the via at the second major surface;
a plurality of conductive elements, wherein individual vias contain at least one conductive element; and
a first adhesive layer adhered to the first major surface of the matrix.

2. The anisotropically conductive structure of claim 1 wherein the conductive element comprises a conductive microsphere having a narrow size distribution, wherein the diameter of the microspheres is less than the thickness of the matrix, less than the size of the opening of the via at the first major surface and greater than the size of the opening of the via at the second major surface.

3. The anisotropically conductive structure of claim 2 wherein the conductive microspheres have a diameter within the range of about 2 to about 150 microns.

4. The anisotropically conductive structure of claim 1 wherein the conductive elements are selected from the group consisting of tin, lead, bismuth, zinc, indium, aluminum, copper, silver, gold, nickel, cobalt, iron, palladium, tungsten, gallium and alloys of these metals, metalized glass, metalized polymers and metalized ceramics.

5. The anisotropically conductive structure of claim 1 wherein the conductive element comprises a plurality of conductive particles dispersed in a binder.

6. The anisotropically conductive structure of claim 1 wherein the matrix comprises a polymeric film.

7. The anisotropically conductive structure of claim 6 wherein the matrix comprises a thermoplastic film.

8. The anisotropically conductive structure of claim 6 wherein the matrix comprises a polymeric film selected from the group consisting of polyolefins, both linear and branched, polyamides, polyimides, polystyrenes, polyurethanes, polysulfones, polysulfides, polyesters, polyvinyls, polyvinyl chloride, polyvinyl acetals, polycarbonates, polyketones, polyethers, phenoxy resins, acrylic polymers, silicone, fluoroelastomer, urethane, acrylic, butyl rubber and copolymers and blends thereof.

9. The anisotropically conductive structure of claim 6 wherein the matrix comprises a multilayer polymeric film.

10. The anisotropically conductive structure of claim 1 further comprising a second adhesive layer adhered to the second major surface of the matrix.

11. The anisotropically conductive structure of claim 1 further comprising a release liner on the first adhesive layer.

12. The anisotropically conductive structure of claim 1 wherein the vias within the array are symmetrically spaced throughout the array.

13. The anisotropically conductive structure of claim 1 wherein the vias within the array are asymmetrically spaced throughout the array.

14. The anisotropically conductive structure of claim 1 wherein the first adhesive comprises a multilayer adhesive.

15. The anisotropically conductive structure of claim 10 wherein the second adhesive comprises a multilayer adhesive.

16. The anisotropically conductive structure of claim 1 wherein at least one predetermined via contains no conductive element.

17. An anisotropically conductive structure comprising:
a dielectric matrix having a substantially uniform thickness and having a first major surface and a second major surface;
an array of vias extending from the first major surface into the thickness of the matrix forming an array of microindentations of uniform depth in the matrix;
a plurality of conductive elements, wherein individual vias contain at least one conductive element; and
a first adhesive layer adhered to the first major surface of the matrix.

18. The anisotropically conductive structure of claim 17 wherein the conductive element comprises a conductive microsphere having a narrow size distribution, wherein the diameter of the microspheres is less than the thickness of the matrix and less than the size of the opening of the via at the first major surface.

19. The anisotropically conductive structure of claim 18 wherein the conductive microspheres have a diameter within the range of about 2 to about 150 microns.

20. The anisotropically conductive structure of claim 17 wherein the conductive elements are selected from the group consisting of tin, lead, bismuth, zinc, indium, aluminum, copper, silver, gold, nickel, cobalt, iron, palladium, tungsten, gallium and alloys of these metals, metalized glass, metalized polymers and metalized ceramics.

21. The anisotropically conductive structure of claim 17 wherein the conductive element comprises a plurality of conductive particles dispersed in a binder.

22. The anisotropically conductive structure of claim 17 wherein the matrix comprises a polymeric film.

23. The anisotropically conductive structure of claim 22 wherein the matrix comprises a thermoplastic film.

24. The anisotropically conductive structure of claim 22 wherein the matrix comprises a polymeric film selected from the group consisting of polyolefins, both linear and branched, polyamides, polyimides, polystyrenes, polyurethanes, polysulfones, polysulfides, polyesters, polyvinyls, polyvinyl chloride, polyvinyl acetals, polycarbonates, polyketones, polyethers, phenoxy resins, acrylic polymers, silicone, fluoroelastomer, urethane, acrylic, butyl rubber and copolymers and blends thereof.

25. The anisotropically conductive structure of claim 22 wherein the matrix comprises a multilayer polymeric film.

26. The anisotropically conductive structure of claim 17 further comprising a second adhesive layer adhered to the second major surface of the matrix.

27. The anisotropically conductive structure of claim 17 further comprising a release liner on the first adhesive layer.

28. The anisotropically conductive structure of claim 17 wherein the vias within the array are symmetrically spaced throughout the array.

29. The anisotropically conductive structure of claim 17 wherein the vias within the array are asymmetrically spaced throughout the array.

30. The anisotropically conductive structure of claim 17 wherein the first adhesive comprises a multilayer adhesive.

31. The anisotropically conductive structure of claim 26 wherein the second adhesive comprises a multilayer adhesive.

32. The anisotropically conductive structure of claim 17 wherein at least one predetermined via contains no conductive element.

33. A method for making an anisotropically conductive structure comprising the steps of:
providing a multilayer structure comprising a dielectric film having a first major surface and a second major surface, and a carrier layer having an inner surface and an outer surface, wherein the inner surface is releasably adhered to the second major surface of the dielectric film;
forming an array of tapered vias extending from the first major surface of the dielectric film into the thickness of the dielectric film with an embossing device having an array of tapered projections projecting therefrom;
filling individual tapered vias with at least one conductive element; and
removing the carrier layer.

34. The method of claim 33 wherein the height of the projections is at least equal to the thickness of the dielectric film.

35. The method of claim 34 wherein the tapered vias extend from the first major surface of the dielectric film to the second major surface of the dielectric film.

36. The method of claim 33 wherein the tapered vias extend from the first major surface into the thickness of the matrix to form an array of microindentations of uniform depth in the matrix.

37. The method of claim 35 wherein the carrier layer has a plurality of channels extending from the inner surface to the outer surface, the channels being aligned with the array of vias formed in the dielectric film.

38. The method of claim 37 wherein filling the tapered vias comprises applying a vacuum to the other surface of the carrier layer.

39. The method of claim 33 wherein the conductive element comprises conductive microspheres.

40. The method of claim 33 wherein filling the tapered vias comprises jetting conductive microspheres into the vias.

41. The method of claim 39 wherein the conductive microspheres have a diameter less than the thickness of the dielectric film and less than the opening of the via at the first major surface.

42. The method of claim 33 wherein the conductive element comprises conductive particles dispersed in a binder.

43. The method of claim 33 wherein the dielectric film comprises a thermoplastic film.

44. The method of claim 33 wherein the dielectric film comprises a film selected from selected from the group consisting of polyolefins, both linear and branched, polyamides, polyimides, polystyrenes, polyurethanes, polysulfones, polysulfides, polyesters, polyvinyls, polyvinyl chloride, polyvinyl acetals, polycarbonates, polyketones, polyethers, phenoxy resins, acrylic polymers, silicone, fluoroelastomer, urethane, acrylic, butyl rubber and copolymers and blends thereof.

45. The method of claim 33 further comprising the step of applying an adhesive layer to at least one of the first major surface of the dielectric film and the second major surface of the dielectric film.

46. The method of claim 45 wherein the adhesive layer is releasably adhered to a release liner.

47. The method of claim 33 wherein the adhesive layer comprises a multilayer adhesive.

48. A method for making an anisotropically conductive structure comprising the steps of:
providing a dielectric film having a first major surface and a second major surface;
forming an array of tapered vias extending from the first major surface of the dielectric film into the thickness of the dielectric film with an embossing device having an array of tapered projections projecting therefrom; and
filling individual the tapered vias with at least one conductive element.

49. The method of claim 48 wherein the height of the projections is less than the thickness of the dielectric film.

50. The method of claim 48 wherein the tapered vias extend from the first major surface into the thickness of the matrix to form an array of microindentations of uniform depth in the matrix.

51. The method of claim 48 wherein the conductive element comprises conductive microspheres.

52. The method of claim 48 wherein filling the tapered vias comprises jetting conductive microspheres into the vias.

53. The method of claim 51 wherein the conductive microspheres have a diameter less than the thickness of the dielectric film and less than the opening of the via at the first major surface.

54. The method of claim 48 wherein the conductive element comprises conductive particles dispersed in a binder.

55. The method of claim 48 wherein the dielectric film comprises a thermoplastic film.

56. The method of claim 48 wherein the dielectric film comprises a film selected from selected from the group consisting of polyolefins, both linear and branched, polyamides, polyimides, polystyrenes, polyurethanes, polysulfones, polysulfides, polyesters, polyvinyls, polyvinyl chloride, polyvinyl acetals, polycarbonates, polyketones, polyethers, phenoxy resins, acrylic polymers, silicone, fluoroelastomer, urethane, acrylic, butyl rubber and copolymers and blends thereof.

57. The method of claim 48 further comprising the step of applying an adhesive layer to at least one of the first major surface of the dielectric film and the second major surface of the dielectric film.

58. The method of claim 57 wherein the adhesive layer is releasably adhered to a release liner.

59. The method of claim 57 wherein the adhesive layer comprises a multilayer adhesive.
